(19) United States
(12) Patent Application Publication
(10) Pub. No.: US 2007/0090475 A1
(43) Pub. Date: Apr. 26, 2007

(54) MEMS PERFORMANCE IMPROVEMENT USING HIGH GRAVITY FORCE CONDITIONING

(75) Inventors: Drew A. Karnick, Blaine, MN (US); Peter H. LaFond, Redmond, WA (US)

Correspondence Address: HONEYWELL INTERNATIONAL INC., 101 COLUMBIA ROAD, P O BOX 2245, MORRISTOWN, NJ, 07962-2245, US

(73) Assignee: HONEYWELL INTERNATIONAL INC., Morristown, NJ (US)

(21) Appl. No.: 11/163,117

(22) Filed: Oct. 5, 2005

(51) Int. Cl. H01L 29/84

(52) U.S. Cl. 257/415

(57) ABSTRACT

A system for conditioning a sensor die. The sensor die may have a sensor wafer and a substrate wafer anodically bonded together. The sensor die may have an inertial device such as an accelerometer or a gyroscope. The device has a scale factor that may change with a bowing of the sensor die. The die may be bonded at a high temperature to bumps on a surface of a package, but may develop a bow when cooled down to a temperature such as room temperature when the coefficients of thermal expansion of the die and the package are different. The bump material may enter a yield state. The package and the die may be subjected to a high gravity environment to reduce or reverse the bow. After the package is removed from the high gravity environment, the bow may return but at a smaller magnitude when subject to similar conditions.

### BACKGROUND

The invention pertains to machined electromechanical systems (MEMS) and particularly to die bonded MEMS. More particularly, the invention pertains to MEMS sensors.

### SUMMARY

The invention includes a procedure for conditioning a MEMS device to relieve a certain amount of stress in the device. Because of such conditioning, the device has improved performance.

### BRIEF DESCRIPTION OF THE DRAWING

FIG. 1 shows a diagram of a gyroscope based on Coriolis principles;

FIG. 2 is a diagram of a basic accelerometer;

FIG. 3a is a sketch of a sensor die;

FIG. 3b shows a fabrication progression for a sensor die;

FIG. 4 shows a package for holding the sensor die of FIG. 3a;

FIG. 5 shows the sensor die situated in the package;

FIGS. 6a, 6b and 6c show examples of bowing of a sensor die due to differing coefficients of thermal expansion of the die and the package, and the effect of a high gravity (G) force;

FIG. 6d shows a bowed sensor die relative to the mounting surface of a package;

FIG. 7a shows profiles of the sensor die due to applications of centrifuge acceleration;

FIG. 7b shows a relationship of a proof mass in a silicon wafer relative to the glass wafer;

FIGS. 8a, 8b and 8c show scale factor errors of inertial measurement units;

FIG. 9 is a graph of scale factor shift of gyroscopes as affected by temperature and high G forces;

FIG. 10 is a graph of scale factor shift of accelerometers as affected by temperature and high G forces;

FIGS. 11 and 12 are charts showing the effects on sensors in a centrifuge;

FIG. 13 shows results of a series of centrifuge runs on accelerometers;

FIG. 14 shows centrifuge test results of inertial measurement units;

FIGS. 15a, 15b and 15c show a build process and structure for a high G inertial sensor;

FIG. 16 exhibits a mounting platform with locations and orientations of accelerometers and gyroscopes for an inertial measurement unit;

FIG. 17a shows an accelerometer in a package;

FIG. 17b shows the accelerometer of FIG. 17a under a high G force; and

FIGS. 18a and 18b show fixtures for high G conditioning of inertial sensor packages.

### DESCRIPTION

The present approach may reduce bowing in MEMS sensor dies, including accelerometers and gyroscopes. Any deformation of the MEMS sense mechanism due to shock which change the geometry of the gaps in the MEMS structure may drive MEMS performance. Reduced bowing and gap changes of the sensors may result in improved MEMS sensor performance over high gravity (G) force and non-high G force environments. One G is a force equivalent to the earth's gravity at about the earth's surface.

MEMS sensors may be bonded into dies using a high temperature bonding process. When the sensor dies are cooled to normal conditions after the bonding process, the sensor die may be pre-bowed and put into a stressed condition because of the materials of the die (i.e., glass and silicon) and the package having different coefficients of thermal expansion (CTEs). This bowing may be verified through measurement and analyses. The die may be attached to gold bumps in a package. The gold bump bonds may be made to enter a yield state in a centrifuge due to the die exerting weight on the gold bump bonds. The die may have a certain amount of weight. When in the high G environment, that weight may act on the gold bump bonds causing them to go into yield. Significantly, when the gold bumps enter into a yield state, then the pre-stresses may be relieved to the sensor die. When the gold bumps have yielded, then the die may “unbend” itself to relieve stress. When returned to a non-high G environment, the gold bumps may return to a non-yielded state, and the stresses on the MEMS sensor die will have been relieved. The G force may have an effect on the die but the key may be the yielding of the gold bump bond and allowing the bowed package to stress relief itself. The effect is not necessarily the G force on the die but rather the effect of the yielding of the gold. The present approach may be applicable where the bonding material between the die and the package can be made to enter into a yield state. With the entry to a yield state and a return to a non-yield state, the MEMS sensor die may have less bow and improved performance when subjected to gun launched environments (or truck shot).

The use of a MEMS sensor in a gun hard launch environment appears to be new. It appears not to be intuitive that scale factor shifts would not continue to happen, or that a scale factor shift is not reversible by applying a force in the opposite direction. Also, it does not appear intuitive that the sensor die warping would change when the centrifuge forces are applied from one instance to another. The scale factor (SF) is a key performance factor for accelerometers and gyroscopes. Scale factor is defined as the ratio of a change in output to a change in the input intended to be measured (IEEE Std 528-1994).

The yield state of the gold bumps may be achieved by putting the MEMS sensor die into centrifuge equipment. Prior to yielding, the MEMS sensor die, the sensor package or higher assembly may be subjected to centrifuge forces. This approach may relieve bowing of the sensor die and the sensor's performance over environments, particularly in those of gun shots, may improve.

Bowing reduction of the die bonded MEMS sensor may be demonstrated with actual measurement of the die, correlation sensor and assembly data, and finite element analysis.

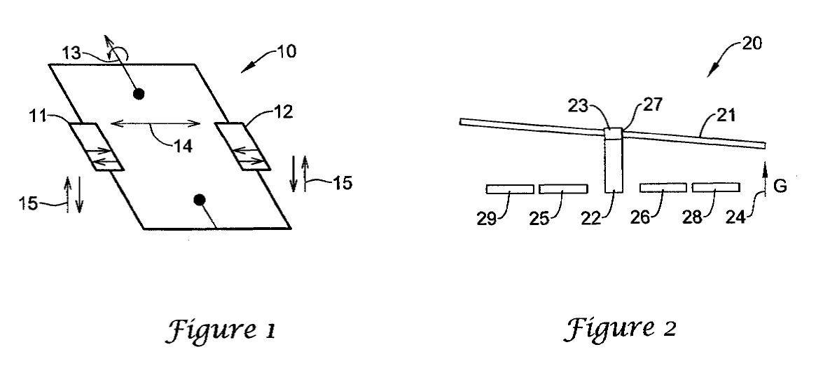

Several kinds of MEMS that may be bonded are gyroscopes and accelerometers. In a MEMS gyroscope, proof masses 11 and 12 may be driven (with a driver) in plane at resonance with opposite oscillatory phases 14, as shown in FIG. 1. Input rate Ω or rotation about an input axis 13 may give rise to a Coriolis force motion 15 normal to the plane of the drive motion 14. Out-of-plane motion 15 may be orders of magnitude smaller than in-plane motion 14 of the proof masses 11 and 12. One may note the relationship in the following formula.

$$m \frac{{ⅆ}^{2} r}{ⅆ {t}^{2}} = F - m Ω ( Ω r ) - 2 m Ω \frac{ⅆ r}{ⅆ t} - m \frac{ⅆ Ω}{ⅆ t} r$$

which may lead to
\vec{F}_{c}=2 m\vec{V}\vec{Ω}
where m is mass, r is the distance from the center of the input rotation rate axis 13 to the center of each proof mass 11 and 12, F is Coriolis force,
Ω
is input rate,
\vec{F}
is a Coriolis force vector,
\vec{V}
is a lateral motion vector 14 of the proof masses 11 and 12 and
\vec{Ω}
is an input rate vector. Electronics for driving and sensing may be associated with the gyroscope.

In a MEMS accelerometer 20, there may be a proof mass 21 situated on a support 22 at a fulcrum 23, as shown in FIG. 2. The proof mass may be a plate-like structure having a greater mass as evidenced by the relative lengths of the proof mass portions on each side of the fulcrum 23. Thus, if there is a G force 24 acting on proof mass 21, it may teeter-totter to the side having the greater mass. There may be sense electrodes 25 and 26 that indicate the position of proof mass 21. Sensor 25 in the instance shown in FIG. 2 may indicate an increased distance of mass 21 from it and sensor 26 correspondingly may indicate a decreased distance of mass 21 from it. The position reading of mass 21 by sensors 25 and 26 may be capacitive. The tilting, teeter-tottering and/or out-of-plane input axis of the pendulous mass 21 may have at fulcrum 23 torsional flexures 27 with strain isolation.

Proof mass 21 may be returned to a horizontal position relative to sensors 25 and 26 and perpendicular to vertical support 22, by mass 21 torque effector elements (drivers) 28 and 29. The elements 28 and 29 may electrostatically rebalance proof mass 21. The greater G force 24 attempting to teeter-totter mass 21, the greater electrostatic force from elements 28 and 29 to maintain the balance of mass 21. The magnitude of the signal fed to elements 28 and 29 needed to balance mass 21 is an indication of the G force 24 acting on the accelerometer 20. The accelerometer 20 may operate with just capacitive mass 21 position sensors 25 and 26 for open loop operation. On the other hand, accelerometer 20 may also operate with mass 21 position rebalance elements 28 and 29 for closed loop operation.

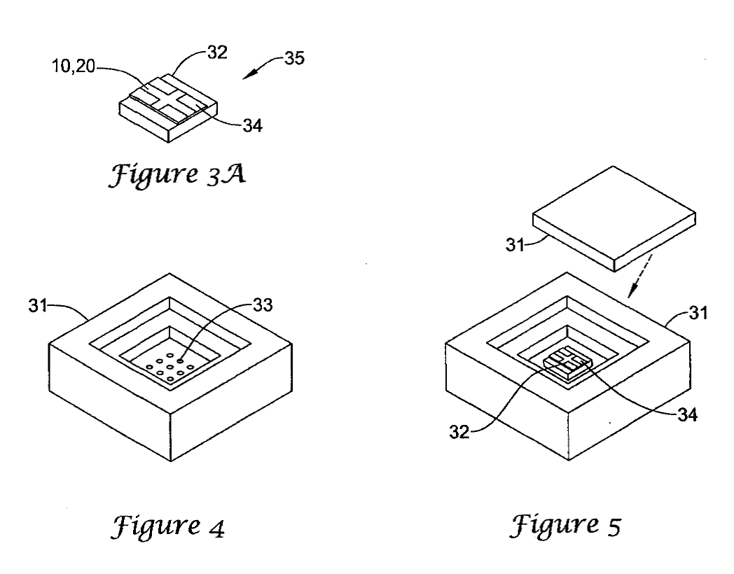

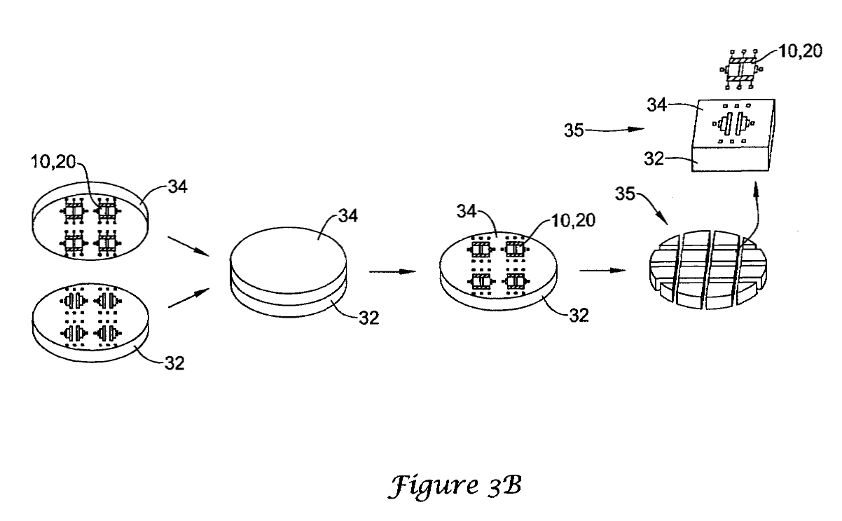

The accelerometer 20 (i.e., as part of a sensor die 35) may be packaged in a leadless chip carrier (LCC) package 31. Similarly, the gyroscope 10 may be put into a LCC package 31. The MEMS silicon gyroscope 10 proof mass and/or accelerometer 20 proof mass may be a part of a silicon wafer that is anodically bonded to a Pyrex™ base 32, as shown in FIG. 3a. Other materials may be used for base 32.

FIG. 3b shows a breakdown of the sensor die 35 in terms of its fabrication steps. Wafer 34 may have RIE patterned inertial sensors 10 or 20 on it. Wafer 34 may be anodically bonded a metalized glass wafer 32. The chemically released MEMS sensors 10, 20 of wafer 34 may be attached to the glass substrate 32. The resultant sensors and substrate may be diced into sensor dies 35.

Gold stud bumps 33 may be situated in the LCC package 31, as shown in FIG. 4, for supporting sensor die 35. Various numbers of gold bumps 33 may be laid out in various patterns. The gold stud bumps may join the Pyrex™ portion 32 of the die stack 35, having the sensor wafer 34, to the LCC package 31, as shown in FIG. 5. Gold bumps 33 may secure the die in the package. Wire bondings may provide electrical connections from the accelerometer 20 or gyroscope 10 proof mass electronic sensors and drivers to connections external of the package 31. The LCC package 31 of FIG. 5 may have a lid attached to it to seal the sensor die 35 within the package. The package 31 may be attached to a post or board with an epoxy.

Sensor modeling with nonlinear gold bumps 33 may reveal a shift over shock problem due to the following items. A cool down from processing may warp the sensor die 35 due to a coefficient of thermal expansion mismatch between the die 35 and the package 31. The gold 33 may be bump bonded to the Pyrex™ portion 32 of the die stack 35 at about 320 degrees C. The sensor die 35 and gold bumps 33 may have residual stresses built in. The sensor die 35 tends to be flat during its attachment to the bumps at the bonding temperature but is curved by the residual stresses caused by the cooling of die 35 and package 31 to room temperature. The gold bumps 33 may be plastically deformed from the processing or fabrication, so additional loading (from temperature or the gun) may cause additional plastic deformation and changes to the sensor die 35 curvature.

Since there is a gap between a proof mass of sensor 10 or 20 and its substrate 34, a change in gap due to bowing may result in a change of capacitance and hence sensor scale factor. The capacitance may be inversely proportional to the gap. The scale factor relationship may be approximately equal to 1/(gap)². Gap variation may be caused by sensor die bending, package 31 mounting due to solder joints and/or underfill where the package is on a board. There may be a yield in the gold bump 33 bond which causes a shift since there may be a scale factor dependence on the bump bonds. Board stresses may translate to gap variation. A gyro sensor may be underfilled on a (e.g., thick printed wiring board, Macor™) post and the post itself may be underfilled on a (sensor) post. The post of an accelerometer may have ceramic or titanium material, as an example.

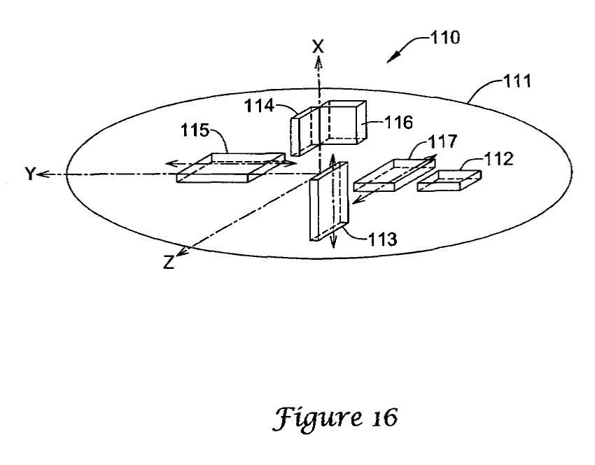

A gyro or accelerometer may have a greater SF change than other sensor axes when mounted on a post in an IMU given that the principal direction of high G acceleration is along the X axis as defined in FIG. 16. The SF changes may be proportional to the G levels. No time dependency has been apparent. Test type variation (ballistic rail gun, centrifuge, etc.) does not appear to be a factor.

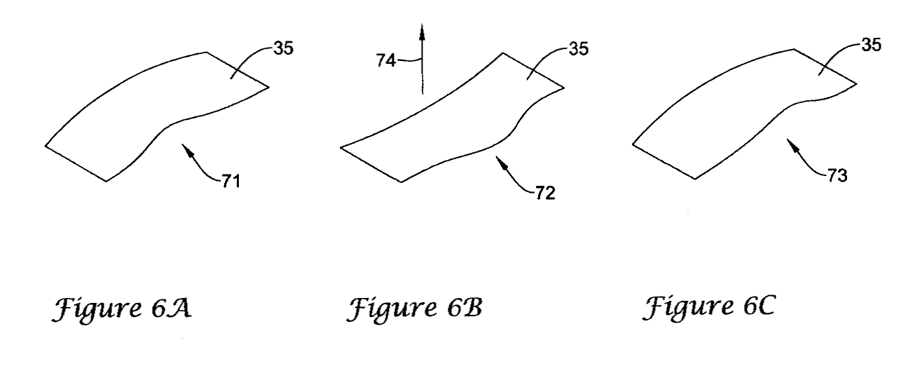

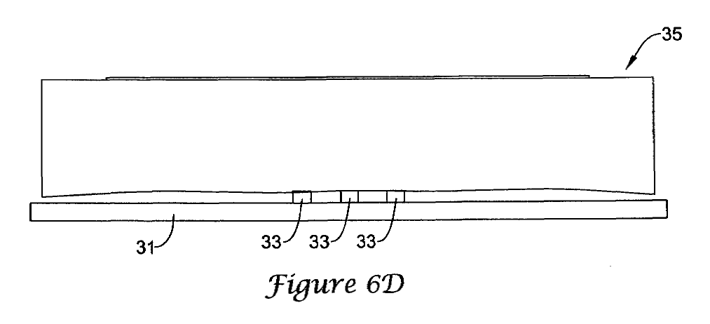

FIG. 6a shows the sensor die 35 before the gun shot application a high G force. There is a bow 71 of the die 35. The gold bumps 33 and package 31 mounting surface are absent for illustrative clarity. FIG. 6b shows the gun G force effect upon the die 35. There is a bow 72 that is less than or in an opposite shape than that of bow 71. The acceleration of the die 35 by the gun is in the up direction 74 of the Figure. After the gun load or acceleration force is no longer affecting the sensor die 35 in FIG. 6c, the die 35 may return only partially to its previous curvature revealing a bow 73 smaller than bow 71 of FIG. 6a. FIG. 6d shows the curvature of the bowed sensor die 35 relative to the mounting surface of package 31. The sensor die 35 is spaced from and secured to the mounting surface of package 31 with gold bumps 33. The curvature or bowing of die 35 is due primarily to a CTE mismatch between the sensor package 31 and die 35. Package 31 is stronger structurally and thus resists bowing better than die 35.

The Pyrex™ wafer 32 and silicon wafer 34 as a bonded combination 35, both before and after a 20 kG (20,000 G) spin, for instance, may be convex but flatter after the spin, as shown by a comparison of FIGS. 6a and 6c. The gap between the Pyrex™ base 32, and the silicon proof mass 11, 12 or 21 changes as one moves outward in any direction from the center of the flexure.

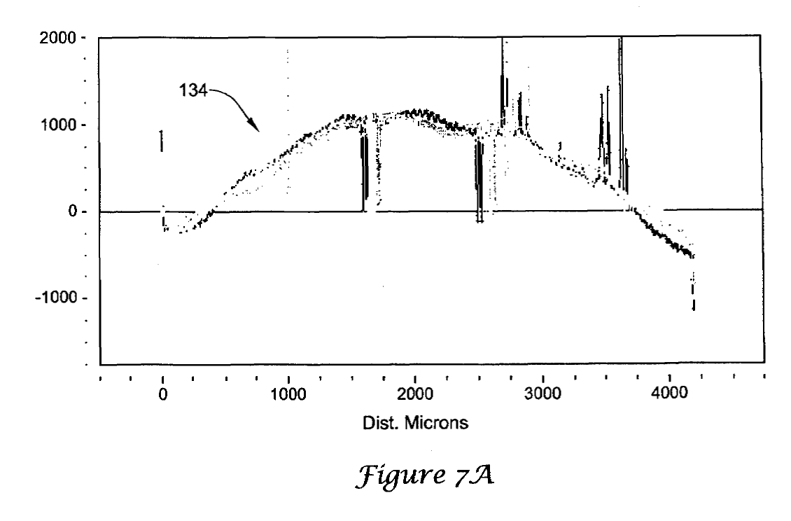

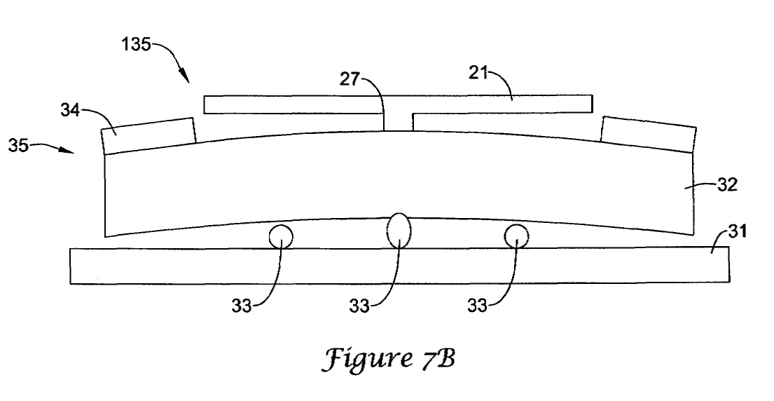

Profiles of a Pyrex™ substrate 32 before and after a high-gain spin show a measurable curvature change. FIG. 7a shows after-spin profiles 134 of the plate, substrate or wafer 32 or die 35 in general. Repeatability appears to be present after an initial conditioning. The gap between the Pyrex™ base 32 and the silicon proof mass of the wafer 34 may increase with distance outward in a direction from the center of a flexure supporting the proof mass in the silicon wafer. One may assume a spin-induced flattening of a Pyrex™ base or wafer 32 of about 0.0001 Angstrom per square micron. The center of the torque pads may be about 600 microns from the flexure of the wafer 32. This may imply a decrease in gap, due to the spin, at the center, of 0.0001*600²=36 Angstroms. FIG. 7b shows a relationship of a proof mass of the silicon wafer 34 relative to the glass wafer 32. The Figure shows a gap 135 between the proof mass 21 and wafer 32 that may increase with distance from flexure 27. With a sensitivity of 60 ppm/Angstrom for a closed-loop accelerometer, this may cause a decrease in the closed-loop SF of about 2160 ppm. The effect on the open-loop may be less since the torque pads are located closer to the flexure and would be positive. There may be some test error here, but the results tend to illustrate the general mechanism.

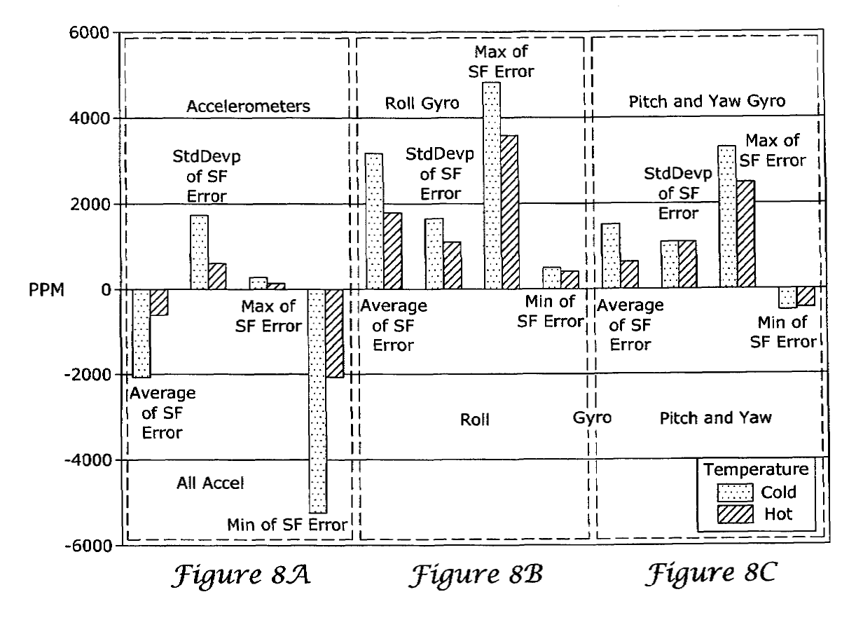

FIGS. 8a, 8b and 8c show data from post gun scale factor measurements of inertial measurement units (IMUs). The left and right portions of each set of measurements represent the hot and cold conditions, respectively. FIG. 8a reveals a scale factor error property of accelerometers in terms of ppm at cold and hot temperatures. The cold temperature is about (−65° F.) −54° C. and the hot temperature is about 85° C. (185° F.). The average of SF error is about −2000 ppm for cold temperatures and about −600 ppm for hot temperatures. The standard elevation of SF error is about 1700 ppm for cold temperatures and about 600 ppm for hot temperatures. The maximum of SF error is about 300 ppm for cold temperatures and about 150 ppm for hot temperatures. The minimum of SF error is about −5300 ppm for cold temperatures and about −2100 ppm for hot temperatures.

FIG. 8b reveals post gun scale factor measurements of roll gyroscopes in terms of ppm like that of FIG. 8a. The average SF error is about 3200 ppm for cold temperatures and about 1800 ppm for hot temperatures. The standard deviation of SF error is about 1700 ppm for cold temperatures and about 1100 ppm for hot temperatures. The maximum of SF error is about 5000 ppm for cold temperatures and about 3600 ppm for hot temperatures. The minimum SF error for cold temperatures is about 500 ppm and for hot temperatures it is about 400 ppm.

FIG. 8c reveals post gun scale factor measurements of pitch and yaw gyroscopes in terms of ppm like that of FIG. 8a. The average SF error is about 1600 ppm for cold temperatures and about 700 ppm for hot temperatures. The standard deviation of the SF shift error is about 1200 ppm for cold and hot temperatures. The maximum of SF error is about 3300 for cold temperatures and about 2300 ppm for hot temperatures. The minimum of SF error is about −400 ppm for cold and hot temperatures.

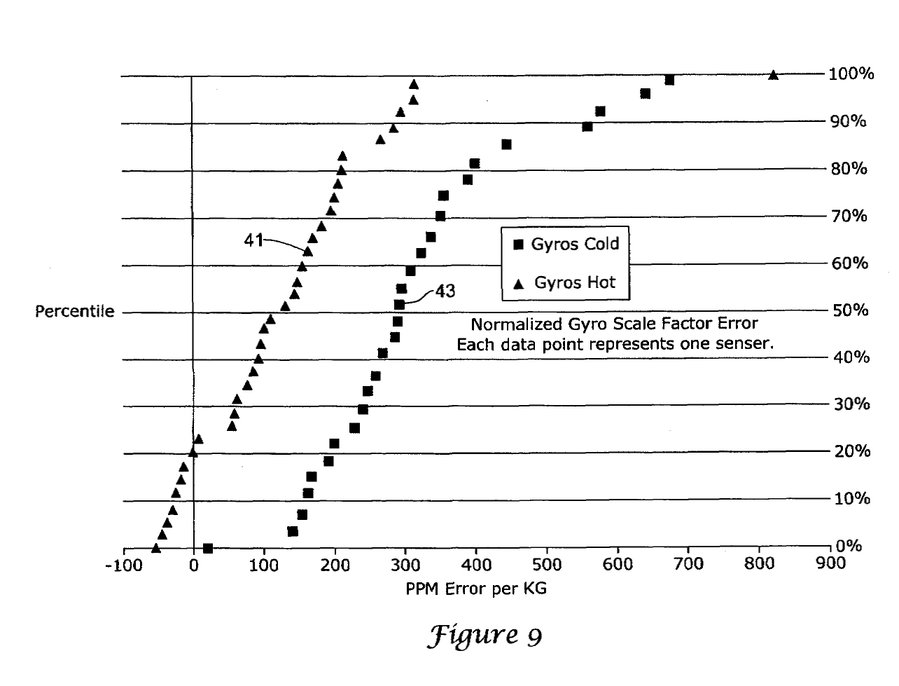

FIG. 9 is a graph showing normalized gyroscope SF shift or error as affected by temperature. It shows a percentile of gyroscopes over temperature normalized versus ppm error per 1000 G (kG). Each data point represents one sensor. The triangle data 41 and square symbol data 43 are about hot gyros and cold gyros, respectively. From the low percentiles to the high percentiles, the hot gyros vary from about −60 ppm error per kG at about the zero percentile to about 300 ppm per kG at about the 97 percentile. There appears to be one outlier at the 100 percentile with about 800 ppm error per kG. The cold gyro data 43 vary from about 120 ppm to about 400 ppm error per kG between the 05 and 82 percentiles. The data 43 vary from about 450 ppm to 700 ppm between the 85 and 100 percentiles. There appears to be one outlier of about 20 ppm close to the zero percentile.

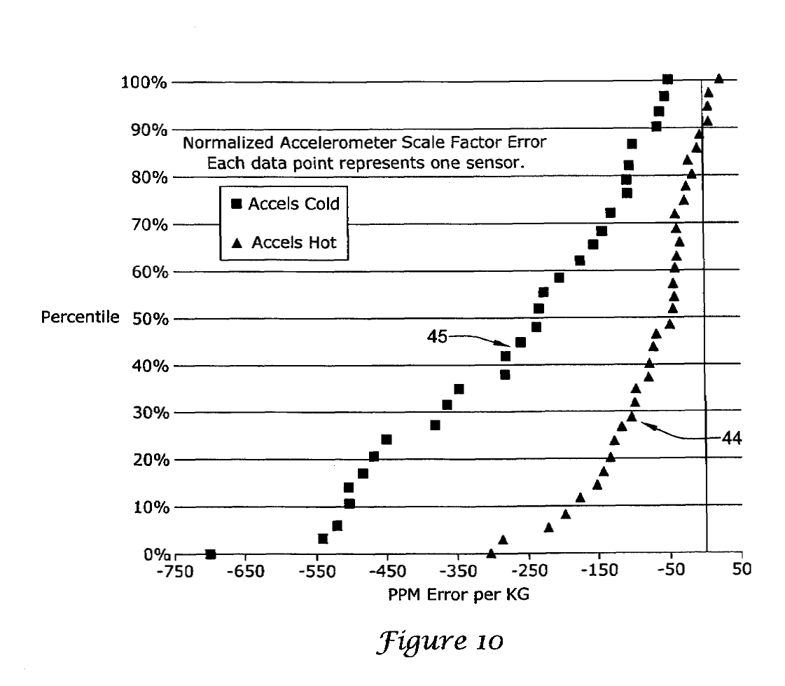

FIG. 10 is a graph showing normalized the accelerometer SF shift or error as affected by temperature. It shows a percentile of normalized accelerometer SF shift versus ppm error per kG. Each data point represents one sensor. The triangle data 44 for hot accelerometers may vary from −300 ppm for low percentiles to about 20 ppm per kG for high percentiles. The square data 45 for cold accelerometers may vary from about −550 ppm for low percentiles to about −80 ppm for high percentiles. There appears to be one outlier of about −700 ppm close to the zero percentile.

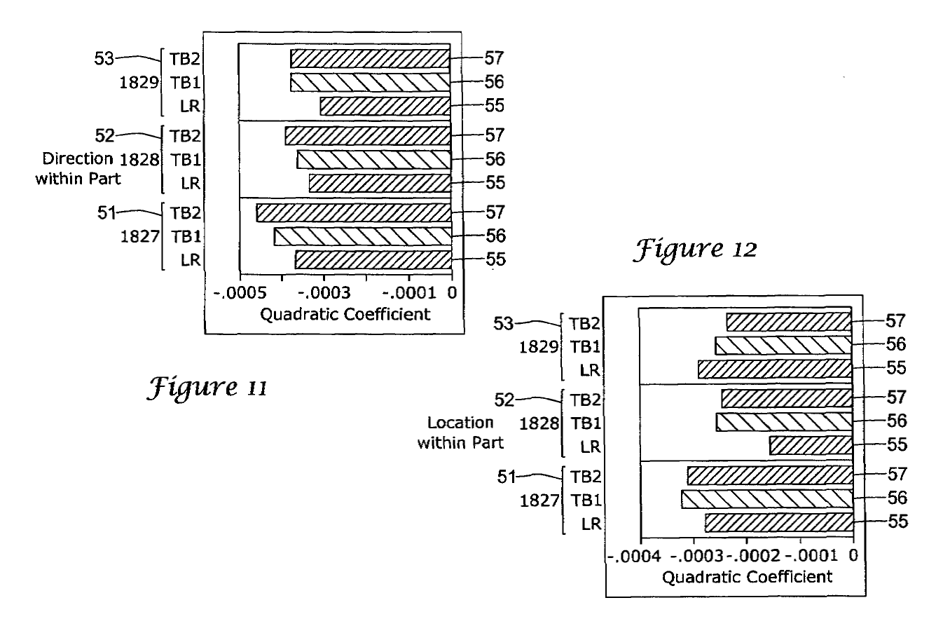

FIGS. 11 and 12 are charts that show the effects for three accelerometer sensors 51, 52 and 53 in pre-spin and post-spin, respectively, in a centrifuge, in directions LR 55, TB1 56 and TB2 57. The Figures show the effects in terms of a quadratic coefficient on a scale from zero to −0.0005 in FIG. 11 and to −0.0004 in FIG. 12. The three sensor units 51, 52 and 53 were spun at 20 kG with profiling before and after the spin. Sensor 51 was put in a 20 kG setback centrifuge (a sensor in tension). Sensor 52 was in a hinge axis and sensor 53 was set forward (a sensor in compression). Regardless of orientation, the effect of the shock was to allow flattening of the Pyrex™ wafer 32 by about 0.1 micron.

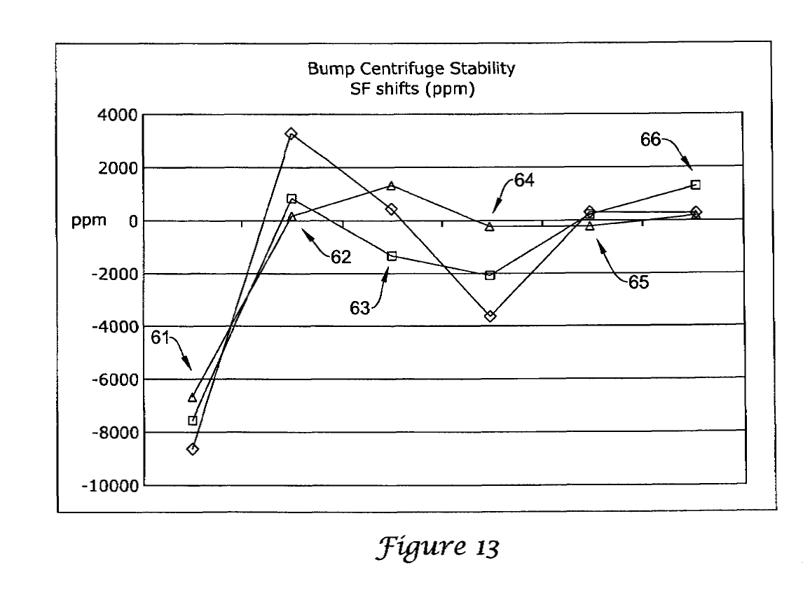

FIG. 13 reveals data from a testing of nine packaged accelerometers. These accelerometers were put through a series of centrifuge runs with tumbles in between. Six centrifuge runs were performed on the (bump 33-attached-to-the-package 31) accelerometers. All of the accelerometers were run closed-loop. The chart of FIG. 13 shows the stability SF shifts in ppm per sequence of the six runs for three groups (as represented by triangle, square and diamond symbols, respectively) of three accelerometers. The first run 61 was a 20 kG setback resulting in an SF shift from about −6700 to −8800 ppm. The second run 62 was a 20 kG set forward resulting in an SF shift from about zero to 3300 ppm. The third run 63 was a 20 kG plus hinge resulting in a SF shift from about −1700 ppm to about 1200 ppm. The fourth run 64 was a 20 kG minus hinge resulting in a SF shift from about −3800 ppm to −200 ppm. The fifth run 65 was a 10 kG setback resulting in an SF shift from about −200 ppm to about 300 ppm. The sixth run 66 was a 10 kG setforward resulting in a SF shift from about 100 ppm to 1400 ppm.

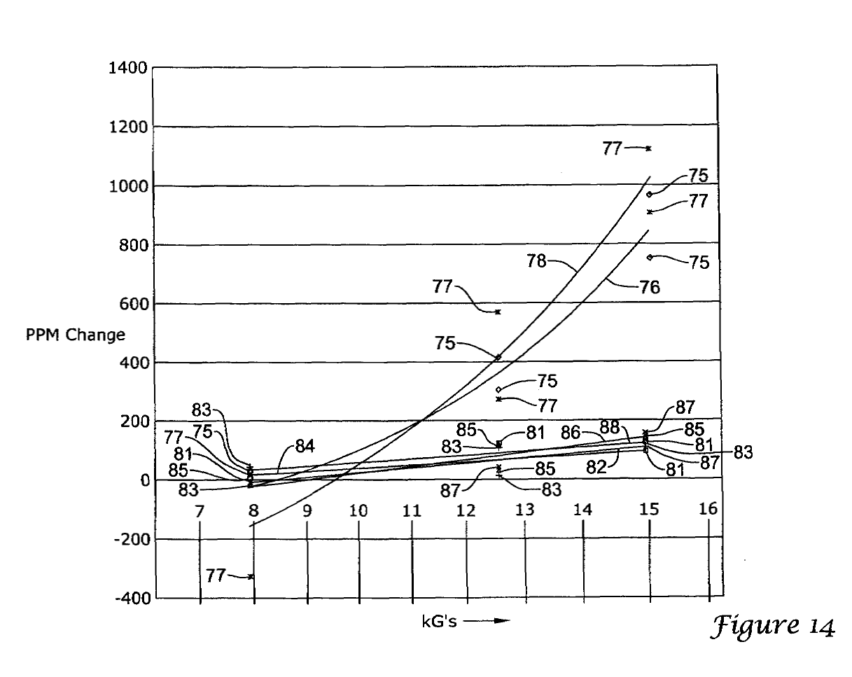

FIG. 14 is a graph of centrifuge test results for an inertial measurement unit (IMU) having three accelerometers and three gyroscopes. The results reveal a roll axis SF shift proportionate to G levels. The shift levels appear to hold with repeated tests. The graph shows the results in terms of ppm change versus kG. The upward curves are of the gyros on a post and the flatter curves are of the gyros on a board.

Centrifuge data points 75 are of a gyro on a post in the axis x for roll sensing. Curve 76 is polynomial fitted from these points. Data points 77 for a second centrifuge test for the same gyro are represented by a polynomial fitted curve 78. Data points 81 are of a gyro on a board in the axis y for pitch sensing. These points 81 are represented by a linear curve 82. Data points 83 are of a second centrifuge test of the y axis gyro. A linear curve 84 represents a fit for the data points 83. Data points 85 are of a gyro on a board in the z axis for yaw sensing. The data points 85 may be represented with a fit of a linear curve 86. Data points 87 are of a second centrifuge test of the z axis gyro. Data points 87 may be represented by a fit of a linear curve 88. Curves 82, 84, 86 and 88 represent data that are nearly the same.

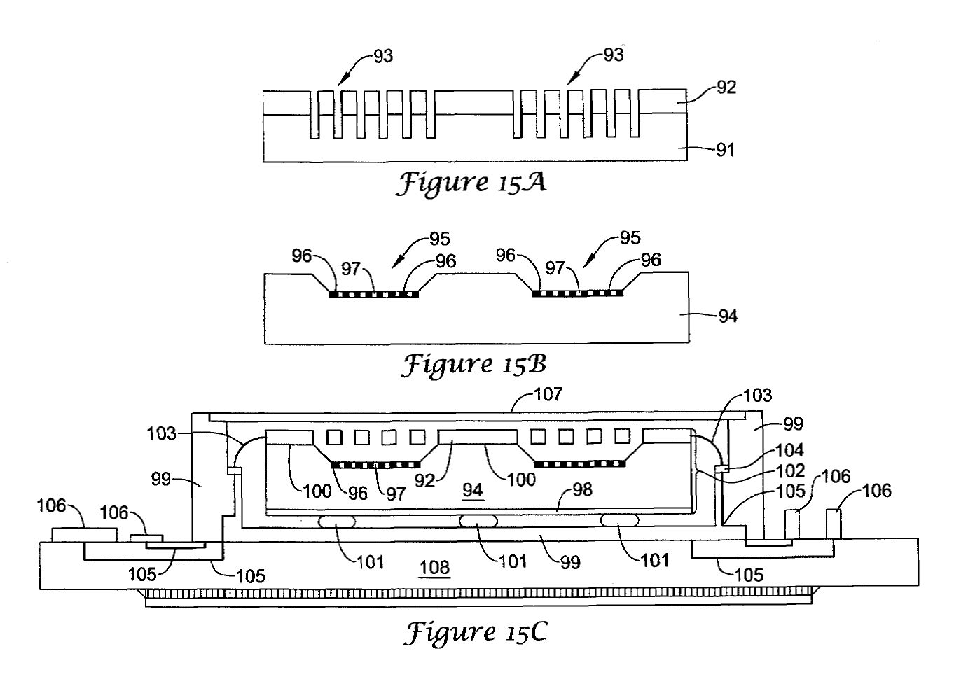

FIG. 15a shows an example of a MEMS process for fabricating an accelerometer or gyroscope for high G usage. For silicon wafer processing, one may begin with silicon starting material 91. On the silicon 91, a P⁺⁺ epitaxial layer 92 may be deposited. A deep RIE trench etch 93 may be effected in layer 92 and wafer 91.

FIG. 15b shows an example of glass wafer processing. A Pyrex™ 7740 glass substrate 94 may be used. An RIE mesa etch 95 may be applied to the glass 94. A metallization 96 may be applied to the areas of etch 95. In addition, an anti-stiction metallization 97 may be applied on the metallization 96 in the areas of the etch 95. In FIG. 15c, there may be an anodic bond of processed silicon wafer 91 of FIG. 15a on the glass wafer. There may be silicon substrate 91 and 92 of FIG. 15a flipped over and attached to the glass substrate 94 using an anodic wafer bond 100. The substrate 91 portion may be removed. A metallization layer 98 may be applied to the backside of the glass substrate 94. An LCC package 99 may be obtained and gold bumps 101 may be placed in the bottom portion of package 99. The substrate 94, with the remaining silicon 92 and the metallization 98, resulting in the MEMS device 102, may be bonded to the gold bumps 101. The device 102 may be wire bonded with electrical connections 103 to terminals 104 that are hooked to provide electrical lines 105 connected to external terminals 106. A cover 107 may be placed on the LCC package 99 in a vacuum to result in a sealing the device 102 within a vacuum environment of package 99. Package 99 may be secured to a structure or board 108 having terminals 106.

FIG. 16 shows a mounting platform 111 of an IMU 110 with a configuration having three accelerometers and three gyroscopes. There may be an x-axis accelerometer 112 mounted parallel to a surface of the platform 111 and an x-axis gyroscope 113 mounted edgewise relative to the platform surface. Also, there may be a y-axis accelerometer 114 mounted edgewise relative to the platform surface and a y-axis gyroscope 115 mounted parallel to the surface of the platform 111. There may be additionally a z-axis accelerometer 116 mounted edgewise relative to the platform surface and a z-axis gyroscope 117 mounted parallel to the surface of the platform 111. The G forces exerted on the platform may be parallel to the x axis, under normal gunshot or centrifuge applications. In a normal gunshot, there may be forces perpendicular to the x axis.

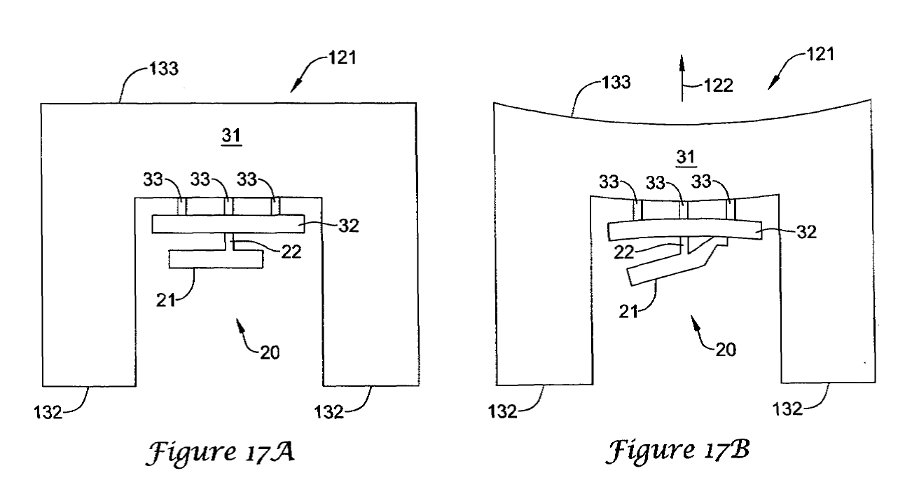

FIGS. 17a and 17b show an assembly 121 containing an accelerometer 20, like that as shown in FIG. 2, having a proof mass 21 situated on a support 22 which in turn is mounted on a Pyrex™ substrate or wafer 32. Substrate or wafer 32 may be attached to an LCC package 31 via support gold bumps 33. Surface 133 of structure 31 may be situated on a board. In FIG. 17a, the assembly 121 is not subject to any perceptible G force. In FIG. 17b, the assembly 121 shows an effect of a significant G force 122 on the accelerometer 20 proof mass 21, base 32, gold bumps 33 and package 31. The G force may be exerted against supports 132 of structure or package 31. Support to the package 31 during a setback acceleration would be at the lid end (i.e., supports 132). This permits the base 133 of the package to deform, as in FIG. 17b, putting great stress on the stud or gold bumps 33. When mounted in an IMU, the package 31 may be joined across the base 133 to a board so that the package 31 deflection is less than that without the board. Thus, the SF shift mechanism may be different in package 31 level testing. This may explain an apparent difference in magnitude between the package 31 and the IMU test results although the polarity of the change appears consistent. The gold bumps 33 yield to a deformation of the base 32. The deformation of these components may return partially to there original shape; however, when subjected to the G force again the deformation change is less on the second application of the G force 122. That is why subjecting the assembly 121 to the force 122 before it is subject to a similar force in an application amounts to a conditioning which should result in a smaller scale factor shift in an accelerometer measurement than if the assembly were not subjected to the conditioning. The same conditioning is applicable to the gyroscope 10 of FIG. 1, and the IMU 110 having accelerometer and gyroscope components enclosed as shown in FIG. 16. For the gyroscope, centrifuging in the shear direction has procured results, at both the package level and as installed in an IMU. At the package level, scale factor shifts may occur from centrifuging in any direction.

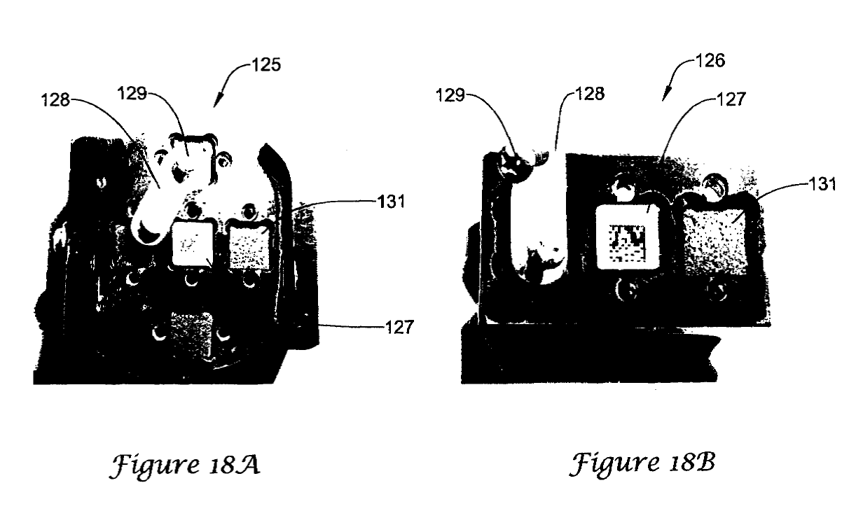

FIGS. 18a and 18b shown fixtures 125 and 126 which may be used for package 31 level conditioning of accelerometers and gyroscopes in a centrifuge, prior to use in high G usage in devices, such as projectiles, being shot from guns or high G force launching devices. Fixture 125 may provide the capability to hold sensors 127, e.g., accelerometers and gyroscopes, in a horizontal position when installed in a centrifuge. A sensor 127 may be held in place by a clamp 128 held by screws 129 having a tightening of about 2.5 inch-pounds. The sensor 127 may be pushed down in to a soft padding 131 providing a non-rigid support with no excessive mounting force. Fixture 126 may similarly hold a sensor 127 in place but for a vertical position when installed in the centrifuge. The sensor 127 may be installed with a side of the package against the fixture 126 so that the sensor does not shift. It likewise uses a soft padding 131.

Closed loop SF shifts appeared to be several times that of corresponding open loop SF shifts, and of opposite signs. The IMU level shifts appeared much smaller than those measured at the sensor level. However, such correlations appeared stronger within an IMU. For the gyroscope, there appeared to be a strong correlation to an axis mounting when centrifuging packages and IMUs, and testing IMUs in a gunshot. Closed loop multi-point tumbles of setback shocked acceleration sensors appeared to indicate that a long paddle side SF drops more than a short paddle side.

High G acceleration of the MEMS sensors and IMUs may involve board yield (to bending) which results in board bow and Pyrex™ bow. The silicon device wafer may be bonded to the Pyrex™ wafer. A bump 33 yield may contribute to the Pyrex™ bow. Gold flexibility may be a factor in the high G acceleration. The Pyrex™ bowing and gold flexing may be factors in the sense gap geometry of a MEMS sensing mechanism. The factors may be particularly relevant to open-loop accelerometer scale factors.

In the present specification, some of the matter may be of a hypothetical or prophetic nature although stated in another manner or tense.

Although the invention has been described with respect to at least one illustrative example, many variations and modifications will become apparent to those skilled in the art upon reading the present specification. It is therefore the intention that the appended claims be interpreted as broadly as possible in view of the prior art to include all such variations and modifications.

What is claimed is:

1. A conditioning system comprising:
a die;
a mounting layer; and
a plurality of bumps attached to a surface of the mounting layer; and
wherein:
the die is bonded to the plurality of bumps at a first temperature to result in a sensor package;
the die of the sensor package has a bowed shape of a first magnitude at a second temperature;
the sensor package is subjected to a first high gravity environment, yielding the bumps between the die and the package, and allowing the die to have a bowed shape of a second magnitude at the second temperature;
the sensor package is removed from the first high gravity environment resulting in the die to have a bowed shape of a third magnitude; and
the first magnitude is greater than the third magnitude.

2. The system of claim 1, wherein:
the die has an inertial sensor;
the inertial sensor has a scale factor; and
a variation of the scale factor is proportional to an absolute value the magnitude of the bowed shape.

3. The system of claim 2, wherein:
the sensor package is subjected to a second high gravity environment forcing the die to have a bowed shape of a fourth magnitude;
the sensor package is removed from the second high gravity environment resulting in the die to have a bowed shape of a fifth magnitude;
the absolute value of the second magnitude is less than the absolute value of the fourth magnitude; and
the first magnitude is greater than the fifth magnitude.

4. The system of claim 3, wherein:
the first magnitude is a positive magnitude;
the second magnitude is a negative magnitude;
the third magnitude is a positive magnitude;
the fourth magnitude is a negative magnitude; and
the fifth magnitude is a positive magnitude.

5. The system of claim 1, wherein the die comprises:
a first wafer of a first material; and
a second wafer of a second material bonded to the first wafer; and
wherein the first wafer is bonded to the plurality of bumps.

6. The system of claim 5, wherein:
the bumps comprise gold; and
the first material comprises glass.

7. The system of claim 6, wherein the second material comprises silicon.

8. The system of claim 7, wherein the second wafer comprises an accelerometer.

9. The system of claim 7, wherein the second wafer comprises a gyroscope.

10. A method for conditioning a die, comprising:
providing a die bonded to bumps on a surface of a package, the die having a bowed shape of a first magnitude;
placing the package in a high gravity environment to cause the bumps to yield and the die to have a bowed shape of second magnitude; and
removing the package from the first high gravity environment to cause the die to have a bowed shape of a third magnitude; and
wherein the first magnitude is greater than the third magnitude.

11. The method of claim 10, wherein:
the first magnitude is positive;
the third magnitude is positive; and
the second magnitude is negative.

12. The method of claim 10, wherein:
the first magnitude is positive;
the third magnitude is positive;
the second magnitude is positive; and
the third magnitude is greater than the second magnitude.

13. The method of claim 10, wherein the high gravity environment provides a force in any direction.

14. The method of claim 10, wherein:
the die comprises an inertial sensor;
the inertial sensor has a scale factor; and
the scale factor is proportional to a magnitude of a bowed shape of the die.

15. The method of claim 13, wherein the high gravity environment is sufficient to cause a material of the bumps to enter into a yield state.

16. The method of claim 15, wherein the high gravity environment is provided by a centrifuge.

17. The method of claim 15, wherein the high gravity environment is provided by a gun launch.

18. A conditioning system comprising:
a package;
a plurality of bumps of a first material attached to a surface of the package;
a first wafer of a second material attached to the plurality of bumps; and
a second wafer of a third material attached to the first wafer; and
wherein:
the first and second wafers form a die;
the die has a bowed shape of a first magnitude when situated in a first gravity environment;
the die has a bowed shape of a second magnitude when situated in a second gravity environment;
the die has a bowed shape of a third magnitude when situated in the first gravity environment; and
the first magnitude is greater than the third magnitude.

19. The system of claim 18, wherein the first material enters a yield state when the die is situated in the first gravity environment.

20. The system of claim 19, wherein the second wafer comprises an inertial instrument.

21. The system of claim 20, wherein:
the inertial instrument has a sensing input signal and a sensing output signal;
there is a scale factor between the sensing input signal and the sensing output signal; and
the scale factor shift is proportional to a magnitude of the bowed shape of the die.

22. The system of 21, further comprising a platform having a plurality of packages, each incorporating the die having an inertial sensor, to result in an inertial measurement unit.
